(19) United States
(12) Patent Application Publication
(10) Pub. No.: US 2008/0038922 A1
(43) Pub. Date: Feb. 14, 2008

(54) Etch-stop layer and method of use

(76) Inventors: Kristina L. Lamers, Fort Collins, CO (US); R. Shane Fazzio, Loveland, CO (US)

Correspondence Address: Kathy Manke;Avago Technologies Limited, 4380 Ziegler Road, Fort Collins, CO, 80525, US

(21) Appl. No.: 11/502,277

(22) Filed: Aug. 10, 2006

(51) Int. Cl. H01L 21/311

(52) U.S. Cl. 438/694

(57) ABSTRACT

An etch-stop layer and method of use is disclosed.

### CROSS-REFERENCE TO RELATED APPLICATIONS

The present application is related to U.S. patent application Ser. No. ______ (Avago Docket Number 10060280-1) filed concurrently herewith and entitled “Electrically Addressable Liquid Dispenser” to Lamers, et al. The disclosure of this application is specifically incorporated herein by reference.

### BACKGROUND

Very large scale integrated circuit (VLSI) processing often includes etching of features in a semiconductor wafer. One type of etching is known as anisotropic etching. Anisotropic etching results in etch rates that are directionally dependent. For example, anisotropic etching is useful in applications where a comparatively large aspect ratio is desired.

Etching is used in the fabrication of microelectromechanical systems (MEMS). One etching technique useful in MEMS fabrication is known as deep reactive ion etching (DRIE). Among other benefits, DRIE provides high-aspect ratio features. In DRIE, etch-stop layers are often used to effectively terminate a deep etching step, which is often difficult to terminate solely by timing the etching step.

Known etch stop layers include certain metals, silicon dioxide (SiO₂) and silicon nitride (Si₃N₄). While these materials function well in many applications, the selectivity to etching many materials used in MEMs fabrication (e.g., Si) is not great enough to allow the use of comparatively thin etch-stop layers. The inability to use comparatively thin etch-stops can limit fabrication options and devices that can be fabricated.

What is needed, therefore, is an etch-stop and fabrication method that overcomes at least the shortcomings described above.

### SUMMARY

In accordance with an illustrative embodiment, a method of fabricating features in a substrate includes: providing an etch-stop layer over the substrate, the etch-stop layer comprising a photoimagable epoxy; and etching the substrate.

In accordance with another illustrative embodiment, an apparatus includes a substrate; an opening in the substrate; and an etch-stop layer disposed over the opening, wherein the etch-stop layer comprises a photoimagable epoxy.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIGS. 1A-1C are cross-sectional views of showing a process sequence of a method of fabricating features in a substrate in accordance with an illustrative embodiment.

FIG. 2 is a cross-sectional view of a substrate processed by a method of an illustrative embodiment.

### DEFINED TERMINOLOGY

The terms ‘a’ or ‘an’, as used herein are defined as one or more than one.

The term ‘plurality’ as used herein is defined as two or more than two.

### DETAILED DESCRIPTION

In the following detailed description, for purposes of explanation and not limitation, specific details are set forth in order to provide a thorough understanding of example embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of apparati, materials and methods known to one of ordinary skill in the art may be omitted so as to not obscure the description of the example embodiments. Such apparati, methods and materials are clearly within the scope of the present teachings.

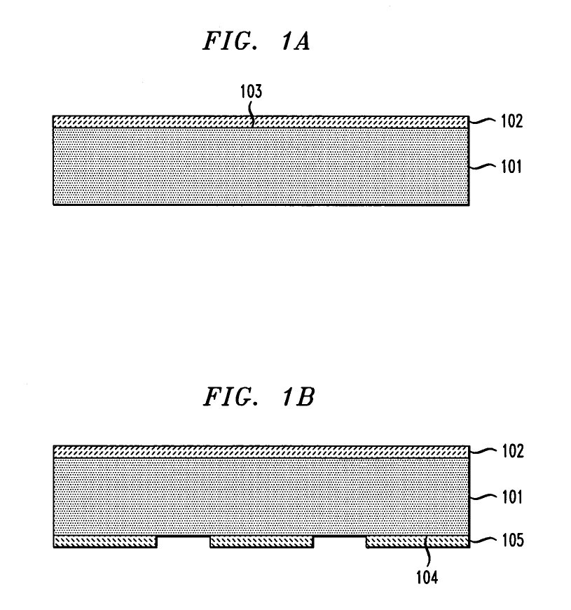

FIGS. 1A-1C are cross-sectional views showing a process sequence of a method in accordance with an illustrative embodiment. The method and materials of the embodiments described are readily applicable to fabricating features in MEMS structures. It is emphasized that this is merely an illustrative application and that other applications are contemplated.

FIG. 1A shows a substrate 101 having an etch-stop layer 102 disposed over a first side 103 of the substrate 101. The substrate 101 may be one of a variety of materials. These materials include, but are not limited to: silicon (Si), silicon germanium (SiGe), silicon-on-insulator (SOI); III-V semiconductors, such as gallium arsenide (GaAs) and indium phosphide (InP); and glass materials.

In the illustrative embodiments, the etch-stop layer 102 is a photoimagable epoxy. The photoimagable epoxy comprises an epoxyfunctional resin adapted for curing by an action of a cation-producing photoinitiator. In certain embodiments, the etch-stop layer 102 is a negative photoresist commercially available from MicroChem Corporation of Newton, Mass. USA and sold under the tradename SU-8 and progeny thereof. This photoresist is also described in U.S. Pat. No. 4,882,245, the disclosure of which is specifically incorporated herein by reference. In other embodiments, the etch-stop layer 102 may be a positive photoresist, such as benzocyclobutene (BCB), which is well known to one of ordinary skill in the art.

The etch-stop layer 102 is spun-on the surface of the first side 103 using standard technique. In certain embodiments, the thickness of the layer 102 is in the range of approximately 2.0 μm to approximately 10.0 μm. In other embodiments, the thickness may be as great as 50.0 μm. In yet other embodiments the thickness may greater than 50.0 μm.

After the etch-stop layer 102 is spun-on, a softbake step is carried out to remove some of the solvents. Next, as shown in FIG. 1B an etch mask 105 is provided on a second side 104 of the substrate 101. The etch mask 105 is formed using known photolithographic methods. In certain embodiments, the etch mask 105 is a hard mask of silicon dioxide or silicon nitride; and in other embodiments the etch-mask 105 is a made from known photoresist materials. After the etch mask 105 is formed and hardened, the substrate 101 is etched by methods described herein.

In certain illustrative embodiments, SU-8 may be disposed over the second side 104 and used to form the etch mask 105. As noted previously, SU-8 is a negative photoresist, and thus can be patterned without the need of another photoresist patterning step. Accordingly, SU-8 or other like-materials can be used as the etch-mask to decrease the complexity and the time of processing the substrate 101. The patterning of the SU-8 layer or similar material to form the etch mask 105 is also carried out by known methods.

After the etch mask 105 is formed, an etching step is carried out to form openings 106 in the substrate as shown in FIG. 1C. In accordance with an illustrative embodiment, the etching of the substrate proceeds using a deep reactive ion etching (DRIE) technique. As is known to those skilled in the MEMS arts, DRIE etching provides a comparatively highly anisotropic etch of a material. Thus, the openings 106 can have a comparatively large aspect ratio resulting in comparatively steep vertical walls.

The DRIE process may be a cryogenic etching method or a time multiplexed or pulsed etching method (known as the Bosch method). The method may include a three-step sequence using SF₆ for etching and C₄F₈ for passivating. As these DRIE methods and materials are known to those skilled in the art, details are omitted to avoid obscuring the description of the embodiments.

As noted, in illustrative embodiments, SU-8 and like materials may be used as the etch-stop layer 102. SU-8 and like materials are highly resistant to SF₆/C₄F₈ and other materials typically used in DRIE processes, allowing the etch-stop layer 102 can be comparatively thin, while providing good clearing of substrate etch. Moreover, the use of these materials as etch-stop layer 105 materials substantially prevents punch-through problems that plague certain known etch-stop materials used in DRIE.

As will be appreciated by one of ordinary skill in the art, a comparatively thin etch-stop layer is useful in MEMS applications in order to achieve desired structures, features and feature dimensions. Beneficially, even though the etch-stop layer 102 of the illustrative embodiments can be as thin as approximately 2.0 μm to approximately 10.0 μm, the selectivity to etching of the substrate 101 is comparatively high, allowing for precision in the forming of the features in the substrate. For example, according to representative embodiments the selectivity was SU-8 to Si was greater than approximately 100:1.

As shown in FIG. 1C, the etch-stop layer 102 spans the opening 106 at locations 107. Many known etch-stops may not have the structural integrity to span an opening of more than a few microns in width, especially when the thickness of the etch-stop layer is as slight as 2.0 μm. Thus, certain fabrication options are restricted by known etch-stops. However, the etch-stop layer 102 of the illustrative embodiments can span openings 106, while providing the structural integrity required. Moreover, the structural strength of the etch-stop layer 105 allows for additional layers to be formed over locations 107 during subsequent processing. Again, this increases the options for fabrication and for the types of devices that can be fabricated.

In accordance with representative embodiments, layers of SU-8 having a thickness in the range of approximately 5.0 μm to approximately 50.0 μm were provided as etch-stop layer 102. The etch-stop layer 102 spanned openings 106, which were circular openings having diameters approximately 500.0 μm and greater. Etch-stop layers of SU-8 having the thicknesses noted above were found to provide suitable structural strength for many applications. In one specific embodiment, an etch-stop layer 102 of SU-8 having a thickness of approximately 10.0 μm to approximately 15.0 μm disposed over an opening 106 required pressure of 90 psi to be broken. It is emphasized that these quantitative examples are merely representative.

Moreover, because the etch-stop layer 105 of the illustrative embodiments is structurally strong, it is generally not pliable. Thus, at locations 107 where it is unsupported by the substrate 101, the etch-stop layer 105 does not appreciably ‘sag’ into or otherwise substantially enter the opening 106.

In many applications this is a useful result. For example, in microfluidic applications laminar flow is realized by comparatively smooth surfaces in the channel of fluid flow such as formed by the walls of the opening 106 and a comparatively flat membrane formed by the etch-stop layer 105 of the example embodiments. By contrast, the flow characteristics of fluid are altered by ‘sagging’ membrane formed by known etch-stop layers such as polyimide or Poly Di-Methyl Siloxane (PDMS) that are not as structurally robust. Among other problems, this can lead to undesirable turbulent fluid flow.

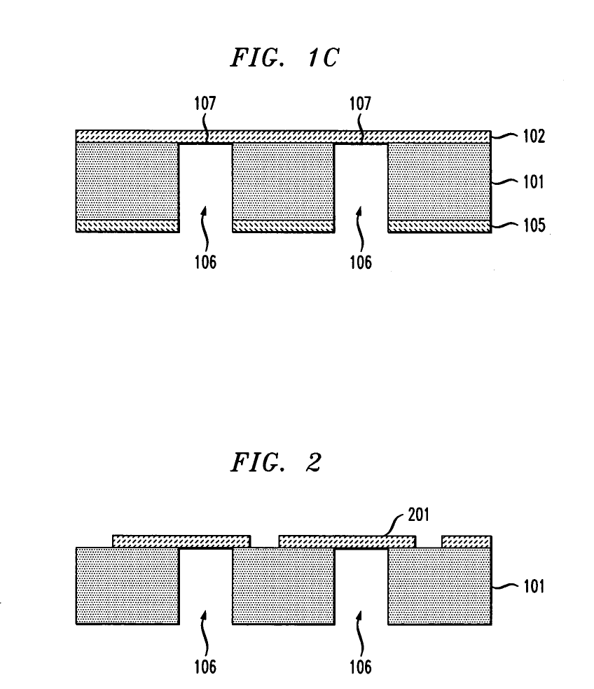

FIG. 2 is a cross-sectional view of a substrate processed by a method of an illustrative embodiment. Many of the details of the methods described in connection with the embodiments of FIGS. 1A-1C apply to the present method as well and are not repeated.

In their function as etch-stop layer 102, SU-8 and like materials of the illustrative embodiments are substantially uncured and substantially unexposed. As noted previously, SU-8 and like materials are photolithographically patternable. In the present embodiment, after the openings 106 are formed, the etch-stop layer 102 is exposed to light of a suitable wavelength through a mask (not shown). After exposure, the etch-stop layer 102 is developed with appropriate developing chemical to provide a photolithographic pattern 201.

Accordingly, the etch-stop layer 102 is adapted to provide two functions: an etch-stop and a resist pattern for subsequent processing. In addition, and unlike many other known etch-stop layers, which are not photolithographically patternable, no additional processing is required to provide the resist pattern. To this end, in order to etch known etch-stop layers in a desired pattern, the etch-stop layer must be coated with a photoresist; the resist must be exposed and developed; and likely stripped after etching or other processing is completed. Thus, because the etch-stop layer 102 of the illustrative embodiments can be photolithographically patterned, an extra masking step can be avoided. Beneficially, the use of SU-8 and like materials for the etch-stop layer 102 makes patterning more efficient and less costly than other etch-stop layers.

In connection with illustrative embodiments, an etch-stop layer and methods of use are described. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A method of fabricating features in a substrate, the method comprising:
providing an etch-stop layer over a first side of the substrate, the etch-stop layer comprising a photoimagable epoxy; and
etching the substrate.

2. A method as claimed in claim 1, further comprising, before the etching, patterning an etch-mask over a second side of the substrate.

3. A method as claimed in claim 2, further comprising not providing a photoresist layer prior to the patterning.

4. A method as claimed in claim 1, wherein the etch-stop layer has a thickness in the range of approximately 2.0 μm and approximately 10.0 μm.

5. A method as claimed in claim 1, wherein the etch-stop layer has a thickness in the range of approximately 2.0 μm and approximately 50.0 μm.

6. A method as claimed in claim 1, wherein the substrate comprises a material chosen from the group consisting of: silicon, gallium arsenide, indium phosphide, silicon germanium, silicon-on-insulator and glass.

7. A method as claimed in claim 1, further comprising:
spin-coating the etch-stop layer over the first side of the substrate; and, before the etching,
forming a patterned layer over the second side of the substrate.

8. A method as claimed in claim 7, wherein the patterned layer is a hard mask.

9. A method as claimed in claim 8, wherein the hard-mask is one of silicon dioxide or silicon nitride.

10. A method as claimed in claim 1, wherein the photoimagable epoxy further comprises an epoxyfunctional resin adapted for curing by an action of a cation-producing photoinitiator.

11. A method as claimed in claim 7, wherein the patterned layer comprises another layer of photoimagable epoxy.

12. A method as claimed in claim 11, wherein the other patterned layer of photoimagable epoxy further comprises an epoxyfunctional resin adapted for curing by an action of a cation-producing photoinitiator.

13. A method as claimed in claim 1, further comprising patterning the etch-stop layer without providing a photoresist over the etch-stop layer.

14. An apparatus, comprising:
a substrate;
an opening in the substrate; and
an etch-stop layer disposed over the opening, wherein the etch-stop layer comprises a photoimagable epoxy.

15. An apparatus as claimed in claim 14, wherein the opening is a microfluidic channel and the etch-stop layer is a sealing layer.

16. An apparatus as claimed in claim 14, wherein the photoimagable epoxy further comprises an epoxyfunctional resin adapted for curing by an action of a cation-producing photoinitiator.

17. An apparatus as claimed in claim 14, wherein the etch-stop layer has a thickness in the range of approximately 2.0 μm and approximately 10.0 μm.

18. An apparatus as claimed in claim 14, wherein the etch-stop layer has a thickness in the range of approximately 2.0 μm and approximately 50.0 μm.

19. An apparatus as claimed in claim 14, wherein the substrate comprises a material chosen from the group consisting of: silicon, gallium arsenide, indium phosphide, silicon germanium, silicon-on-insulator and glass.
